(19) United States
(12) Patent Application Publication
(10) Pub. No.: US 2023/0201992 A1
(43) Pub. Date: Jun. 29, 2023

(54) METHOD OF POLISHING A SUBSTRATE HAVING DEPOSITED AMORPHOUS CARBON LAYER

(71) Applicants: DONGJIN SEMICHEM CO., LTD., Incheon (KR); SAMSUNG ELECTRONICS CO., LTD., Suwon-si (KR)

(72) Inventors: Heesuk KIM, Hwaseong-si (KR); Goo Hwa LEE, Hwaseong-si (KR); Jaehong YOO, Hwaseong-si (KR); Jong Dai PARK, Hwaseong-si (KR); Jae Hyun KIM, Hwaseong-si (KR); Juyoung YUN, Hwaseong-si (KR); Jisung LEE, Hwaseong-si (KR); Seonung CHOI, Pyeongtaek-si (KR); Jae-hwi LEE, Pyeongtaek-si (KR); Bong Soo AHN, Hwaseong-si (KR); Sam-jong CHOI, Hwaseong-si (KR)

(21) Appl. No.: 18/086,871

(22) Filed: Dec. 22, 2022

(30) Foreign Application Priority Data
Dec. 28, 2021 (KR) 10-2021-0189491

(51) Int. Cl. B24B 37/04

(52) U.S. Cl. CPC B24B 37/042

(57) ABSTRACT

A method of polishing a substrate having amorphous carbon layer deposited thereon removes protrusions on the ACL surface by using a soft pad with a low hardness and a polishing slurry containing non-spherical modified fumed silica with high friction force with the surface.

### CROSS-REFERENCE TO RELATED APPLICATION(S)

This application claims priority to and the benefit of Korean Patent Application No. 10-2021-0189491 filed on Dec. 28, 2021 with the Korean Intellectual Property Office, the entire contents of which are incorporated herein by reference.

### BACKGROUND

### (A) Field of the Invention

The present disclosure relates to a method of polishing a substrate having amorphous carbon layer deposited thereon that can effectively remove surface protrusions of an amorphous carbon layer using a CMP slurry composition for amorphous carbon layer (ACL) and a soft polishing pad.

### (B) Description of the Related Art

Along with the development of semiconductor devices, the size of the devices is getting smaller and the required performance is getting higher. Thus, research for miniaturization of the line width and the high integration degree of the devices is rapidly progressing.

In order to achieve high integration of semiconductor devices, a multi-layer stacking technique that stacks circuits on top of each other and a hardmask having a higher thickness are required. This is because when a high structure is made using a photoresist (PR) with a high thickness as in the past, the aspect ratio becomes high and the PR pattern collapses.

In order to solve the above problem, a method of patterning a PR by using Spin on Carbon (SOC) or Spin on Hardmark (SOH) hardmask, or an amorphous carbon layer (ACL) hardmask as a sacrificial layer is used.

However, SOC and SOH using spin coating have poor etch resistance compared to ACL of Chemical Vapor Deposition (hereinafter, CVD) method, which is not appropriate for devices that require increasingly thick hardmasks.

Therefore, there is an increasing demand for utilizing CVD-type ACL hardmasks in the process for highly integrated next-generation devices.

By the way, the CVD system utilizes chemical vapor during ACL deposition, and clusters or carbon particles generated by the concentration of chemical vapors as shown in FIG. 1 are formed on the surface of the substrate having ACL deposited thereon. These clusters or particles (hereinafter referred to as protrusions) cause the reduction of the yield and productivity.

Recently, in order to remove the protrusions generated on the ACL surface to produce a hard mask having a uniform flatness, a Chemical Mechanical Polishing (CMP) technique is required, but a CMP slurry composition capable of removing surface protrusions by effectively polishing ACL has not yet been developed.

In addition, usually, ACL has a very strong carbon-carbon bond and thus exhibits chemical inertness, and the higher the CVD deposition temperature, the more difficult it becomes to polish the ACL surface having high hardness. Moreover, an appropriate CMP process method matching the purpose is required to efficiently remove only the protrusions on the ACL surface.

### SUMMARY

It is an object of the present invention to provide a method of polishing a substrate having an amorphous carbon layer deposited thereon that effectively removes only the surface protrusions on the amorphous carbon layer (ACL) deposited on the substrate through a CVD system.

It is another object of the present invention to provide a method of polishing a substrate having amorphous carbon layer deposited thereon that can more effectively manufacture a highly integrated semiconductor device by improving the utilization of an ACL hardmask by using the polishing method.

According to one embodiment, there is provided a method of polishing a substrate having amorphous carbon layer deposited thereon, the method comprising:
providing a substrate containing an amorphous carbon layer deposited by a CVD system and a soft polishing pad, and
supplying a polishing slurry composition containing modified fumed silica between the substrate having amorphous carbon layer deposited thereon and the soft polishing pad to perform polishing.

According to the present disclosure, as the ACL surface protrusions on the substrate on which ACL is deposited by a CVD system is to be polished, and a chemical mechanical polishing slurry composition containing a soft polishing pad with a particularly low hardness and a modified fumed silica is used, provided is a method of polishing a substrate having ACL deposited thereon that can efficiently remove only ACL surface protrusions.

By such a method, most of the ACL surface protrusions deposited by the CVD system can be removed without damage to the substrate, and thus, an ACL hardmask having uniform flatness can be achieved. Therefore, the utilization of the ACL hardmask in the manufacturing process of a semiconductor device can be increased compared to conventional processes.

Therefore, by using the method of polishing the semiconductor substrate according to one embodiment, a highly integrated semiconductor device with miniaturization of a line width can be more effectively achieved.

### BRIEF DESCRIPTION OF THE DRAWINGS

FIG. 1 shows the shape of ACL surface protrusions generated by a CVD system (SEM measurement).

FIG. 2 schematically shows a comparison of the method of removing ACL surface protrusions according to the polishing method of the substrate having ACL deposited thereon of Comparative Example 1 and Example 1.

FIG. 3 shows an example of a defect inspection apparatus for a substrate (wafer).

FIG. 4 confirms whether or not surface protrusions are polished before and after polishing through SEM images of the apparatus after measuring the positions of the protrusions with the RV-G7 apparatus (panel (a): protrusion remaining, panel (b) split (remove)).

### DETAILED DESCRIPTION

Hereinafter, embodiments of the present disclosure will be described in more detail. It will be understood that words or terms used in the specification and the appended claims shall not be interpreted as the meaning defined in commonly used dictionaries. It will be further understood that the words or terms should be interpreted as having a meaning that is consistent with their meaning in the context of the relevant art and the technical idea of the invention, based on the principle that an inventor may properly define the meaning of the words or terms to best explain the invention.

The term “including” or “comprising” as used herein specifies a specific feature, region, integer, step, action, element and/or component, but does not exclude the presence or addition of a different specific feature, region, integer, step, action, element, and/or component.

Hereinafter, embodiments of the present disclosure will be described in detail so that those skilled in the art can easily implement them. The embodiments can be modified in various different ways, and the present disclosure is not limited to the specific embodiments set forth herein.

A method for polishing a semiconductor substrate according to one embodiment will be described below.

According to one embodiment of the disclosure, a method of polishing a substrate having amorphous carbon layer deposited thereon may include providing a substrate containing an amorphous carbon layer deposited by a CVD system and a soft polishing pad, and supplying a polishing slurry composition containing modified fumed silica between the substrate having amorphous carbon layer deposited thereon and the soft polishing pad to perform polishing.

The method is provided for polishing an amorphous carbon layer (hereinafter, referred to as ACL) formed on a semiconductor substrate by a CVD system.

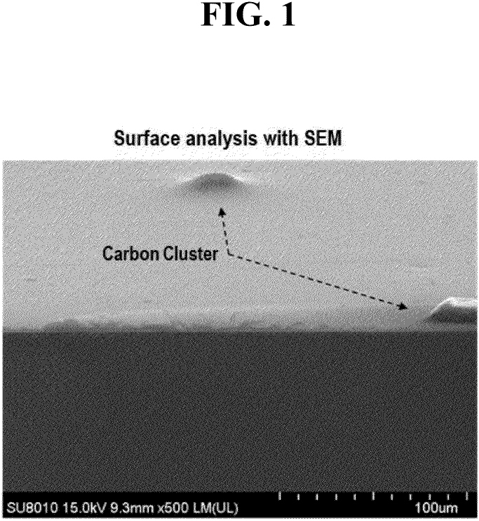

Since the ACL is formed by depositing on the substrate by the CVD system, it includes surface protrusions as shown in FIG. 1 and thus, a method for removing the same is necessary. However, conventionally, the ACL surface protrusions could not be effectively removed, which leads to deterioration in surface flatness.

Thus, the polishing method of the substrate having amorphous carbon layer deposited thereon according to one embodiment has a feature that the friction force with the ACL surface protrusions can be increased to effectively remove the surface protrusions.

Also, the polishing method has a feature that ACL surface protrusions (irregularities) are removed by applying a soft pad rather than a hard pad in the polishing process. That is, the polishing method can be applied to all polishing pads used in a normal CMP process, but more effectively, in addition to using the chemical mechanical polishing slurry mentioned above, a soft pad with a low hardness can be applied to prevent the problem of excessive breakage of the ACL surface protrusions.

The method of polishing the substrate having deposed ACL will be described below.

Since carbon projections (i.e., ACL surface projections) are formed on the surface of the substrate (wafter) during ACL deposition by a CVD system, the present disclosure aims at providing a polishing method for effectively removing the surface protrusions from the substrate having ACL deposited thereon.

Specifically, as is commonly known to those skilled in the art, it has been naturally accepted that it is advantageous to use a hard type pad to remove the surfaces protrusions through CMP, and colloidal silica particles are more effective than fumed silica particles for preventing surface defects after CMP.

However, since a hard pad has a higher hardness than a soft pad, protrusions on the ACL surface may be rather broken or torn off during the polishing process, which may aggravate surface defects of the ACL.

In addition, even if fumed silica is applied in a general polishing process using a hard pad, the ACL surface protrusions cannot be effectively removed due to the high hardness of the hard pad, and thus, the protrusion removal efficiency decreases, so that even if the ACL is applied as a hard mask, the yield and productivity decreases.

In addition, even if a soft pad is used, the removal efficiency of ACL surface protrusions may be deteriorated as compared with fumed silica during application of colloidal silica. That is, when colloidal silica is applied as polishing particles, the spherical colloidal silica particles have a smooth surface and roll only around the ACL surface protrusions, thus deteriorating the surface friction force and failing to properly remove the surface protrusions.

Thus, according to one embodiment of the invention, by applying a soft pad advantageous for the removal of ACL surface protrusions is applied and, at the same time, a polishing slurry incorporating modified fumed silica particles as an abrasive (i.e., abrasive particles) is used, whereby it is possible to provide a method of polishing a substrate having ACL deposited thereon, that selectively and effectively removes most of the surface protrusions from the substrate having ACL deposited thereon.

That is, since soft pads have a lower hardness and thus, the ACL surface protrusions are not broken or torn off during the polishing process, ACL surface protrusions can be removed more effectively than by hard pads.

In addition, since the modified fumed silica used as the abrasive exhibits a non-spherical shape with higher friction force with the surface than colloidal silica, it may contribute to selectively removing only protrusions from the ACL surface.

Therefore, the polishing slurry according to one embodiment herein can exhibit efficient polishing performance for a hard carbon-based layer such as ACL or Diamond-Like Carbon (DLC) made by a CVD deposition system. In particular, the chemical-mechanical polishing slurry can assist in effectively removing the protrusions generated on the surface of the ACL to form a uniform surface. Therefore, as described above, the object to be polished herein may be ACL surface protrusions on the substrate on which ACL is deposited by the CVD system.

The ACL may be formed by depositing ACL on the semiconductor substrate using a general CVD system in a chemical mechanical polishing process of a semiconductor substrate during the manufacturing process of the semiconductor device.

The modified fumed silica may be fumed silica modified with an aluminum compound.

According to one embodiment, the modified fumed silica may include an amorphous Al-modified fumed silica having an average particle size of greater than 150 nm and equal to or less than 250. The average particle size of the modified fumed silica may mean a particle size in which Al-modified fumed silica of a predetermined size is dispersed and distributed in a dispersed aqueous solution by Disper Mixer, and the average particle size can be measured using a dynamic light scattering method.

The modified fumed silica may be contained in an amount of 0.1 to 20% by weight based on the total weight of the polishing slurry composition.

The polishing slurry composition may further include a surfactant.

Further, the soft polishing pad may have a Shore A hardness of less than 80.

Such a polishing method according to one embodiment can exhibit an ACL protrusion removal effect close to a maximum of 100%, only when the soft pad and the fumed silica particles are combined as described above. That is, according to the method of the present disclosure, by removing most of the ACL surface protrusions deposited by a CVD system without damage to the substrate, a highly integrated semiconductor device with miniaturization of a line width can be achieved.

Further, the surface protrusion removal efficiency of the amorphous carbon layer measured by the following method may be at least 80%:

the surface protrusion removal efficiency of the amorphous carbon layer is quantitatively calculated according to the following Equation 1, after confirming the number and position coordinates of the projections on the substrate having deposited amorphous carbon layer with an SP2 or SP5 inspection apparatus, measuring the position of the corresponding protrusions with an RV-G7 apparatus, and then confirming the state of removing the protrusions before and after polishing through the SEM image of the apparatus.

$$\begin{matrix}\text{Protrusion removal efficiency of amorphous carbon layer} \left(\text{\%}\right) = \\ \left\{\left(\text{Total number of surface protrusions before polishing -}\right)\right) \\ \left(\text{Total number of surface protrusions after polishing}\right) / \text{Total number} \\ \left(\text{of surface protrusions before polishing}\right\} \times 100\end{matrix}$$

Specifically, according to the polishing method, the surface protrusion removal efficiency of the ACL may be at least 80%.

More specifically, the surface protrusion removal efficiency of the ACL may be 80% or more or 90 to 100%.

The polishing method can exhibit a surface protrusion removal efficiency of 80% or more even if the size of the surface protrusion of the ACL is large. The smaller the size of the surface protrusion, the more improved the removal efficiency.

For example, when the surface protrusion size of the ACL is about 3 µm or more, the surface protrusion removal efficiency may be 80% or more or 83% or more. Further, when the surface protrusion size of the ACL is about 1 to 3 µm, its removal efficiency may be 90% or more, or 95% to 97%. In particular, when the surface protrusion size of the ACL is about 1 µm or less, its removal efficiency is 97% to 100%, which can completely remove the surface protrusions of ACL by a maximum of 100%.

In addition, the surface protrusion removal efficiency of the ACL can be measured using a surface defect inspection apparatus of a substrate (wafer) and an apparatus equipped with an SEM capable of measuring the position of the protrusions.

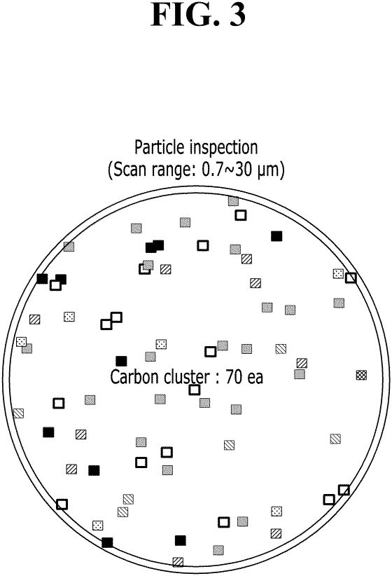

The substrate defect inspection apparatus may utilize a particle counter that inspects surface defects by scanning the substrate surface having ACL deposited thereon with a laser. FIG. 3 shows an example of a defect inspection apparatus for a substrate (wafer).

The particle counter may utilize an SP2 or SP5 inspection apparatus as shown in FIG. 3.

The apparatus equipped with an SEM capable of confirming the coordinates of the protrusions can utilize an RV-G7 equipment equipped with an SEM.

Therefore, the surface protrusion removal efficiency of the ACL can be quantitatively calculated according to Equation 1.

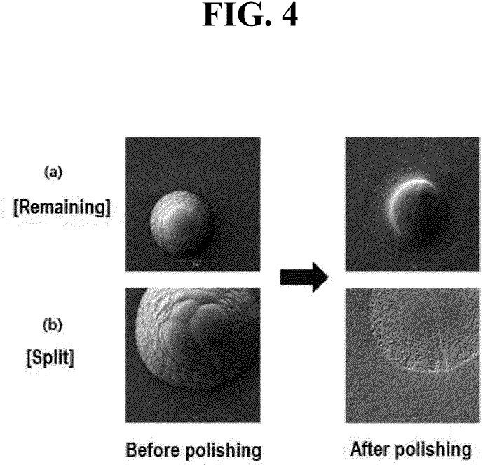

Meanwhile, FIG. 4 confirms whether or not surface protrusions are polished before and after polishing through SEM images of the apparatus after measuring the positions of the protrusions with the RV-G7 apparatus (panel (a): protrusion remaining, panel (b) split (remove)).

As clearly shown in panel (a) of FIG. 4, if the protrusions remain or break before and after CMP polishing, it can be considered that the protrusions are not removed. Also, when all the protrusions are removed after CMP polishing, it is possible to clearly distinguish them as shown in the SEM photograph of panel (b) of FIG. 4.

Thus, the protrusion shape before and after CMP is measured using two apparatus of the particle counter and RV-G7 instrument, and the surface projection efficiency can be calculated quantitatively by directly observing the protrusions through the SEM of the RV-G7 equipment.

Therefore, the polishing method can provide a structure having excellent surface flatness of the substrate having ACL deposited thereon, thus maximizing the utilization of the hard mask using the ACL to provide a highly integrated semiconductor device with excellent performance.

Meanwhile, as described above, the chemical mechanical polishing slurry composition includes a specific abrasive as an essential component.

The abrasive used herein may include composite particles in which fumed silica particles are modified with a surface modifier such as an aluminum cluster by a surface modifier.

That is, as described above, the modified fumed silica may be fumed silica modified with an aluminum compound.

Specifically, the abrasive uses a silica-based abrasive that is excellent in dispersion stability and causes minimal scratches during the CMP process, among ordinary abrasives for performing chemical mechanical polishing.

The silica-based abrasive includes fumed silica or colloidal silica. Among them, in order to selectively and easily remove only the protrusions on the ACL surface, non-spherical fumed silica having high friction force with the surface is used instead of colloidal silica.

In particular, according to one embodiment, the non-spherical fumed silica has a feature that it is a modified fumed silica modified with an aluminum-based compound as a surface modifier.

The modified fumed silica may have a structure in which an aluminum compound (i.e., aluminum cluster) as a keggin cluster is bonded to all or part of the fumed silica surface using a keggin cluster bonding method. Therefore, the modified fumed silica may mean Al-modified fumed silica.

Such modified fumed silica exhibits an irregular, non-spherical shape of a certain size, and has a higher friction force with the ACL surface than the spherical silica, so that most of the protrusions on the ACL surface can be removed more effectively, and the flatness can be improved.

Further, the modified fumed silica may include aluminum clusters on the surface of the fumed silica through covalent bonding, ionic bonding, or physical bonding between the aluminum-based compound and the fumed silica.

For example, fumed silica particles and an aluminum-based compound can be added and dispersed in water,

Aluminum-modified fumed silica in which aluminum clusters are formed on the surface thereof can be prepared by adding and dispersing fumed silica particles and an aluminum-based compound in water, and then subjecting to a modification reaction through stirring for a certain time, thereby preparing Al-modified fumed silica with aluminum clusters formed on the surface thereof.

Therefore, the modified fumed silica, finally obtained after the modification reaction, may include amorphous Al-modified fumed silica having an average particle size of greater than 150 nm and equal to or less than 250 nm. More specifically, the average particle size of the modified fumed silica may be 180 nm to 190 nm.

At this time, the purpose of the present disclosure is not to reduce scratches on the surface to be polished, but to remove ACL surface protrusions formed on the surface to be polished, so that the particle size need not be too small, below 50 nm. Further, there is no significant change in the average size of the fumed silica particles before and after modification according to the present disclosure.

However, in consideration of the efficient removal of ACL surface protrusions, the modified fumed silica particles are dispersed and used within the above range.

That is, when the average particle size of the modified fumed silica is 150 nm or less, the effect of removing the ACL surface protrusions may not be improved to a desired degree, so that the ACL surface protrusions may remain on the substrate. In addition, when the average particle size is greater than 250 nm, the ACL surface protrusions may be rather broken or torn off during the polishing process.

The modified fumed silica may be contained in an amount of 0.1 to 20% by weight based on the total weight of the polishing slurry composition.

Specifically, the content of the fumed silica may include 0.1 to 20% by weight, 1 to 10% by weight, or 3 to 7% by weight, and more specifically, 3 to 5% by weight, based on the total weight of the chemical mechanical polishing slurry. If the content of the fumed silica is less than 0.1% by weight, there is a problem that the polishing performance is poor and the ACL protrusions remain without being completely removed. If the content is more than 20% by weight, the content is excessive, scratches by the polishing particles may be generated on the surface of the layer to be polished.

Additionally, the polishing slurry composition may further contain a surface modifier for providing modified fumed silica.

The surface modifier serves to modify the surface of the abrasive with Al, thereby changing the surface charges into strong positive charges, and can act as aluminum clusters. This can further improve the ACL polishing properties of the modified fumed silica.

The type of the surface modifier acting as the aluminum cluster is not limited, and examples thereof may include one or more aluminum-based compounds selected from the group consisting of aluminum sulfate, ammonium aluminum sulfate, aluminum potassium sulfate, aluminum nitrate, trimethylaluminum, and aluminum phosphide. Further, the aluminum-based compound is an aluminum cluster, and may include one or more cationic complex structures selected from the group consisting of [Al(OH)]²⁺, [Al(OH)₂]⁺, [Al₂(OH)₂(H₂O)^{g}]⁴⁺, [Al₁₃O₄(OH)₂₄(H₂O)₁₂]⁷⁺ and Al₂O₈Al₂₈(OH)₅₆(H₂O)₂₆]¹⁸⁺, but the present disclosure is not limited thereto.

The content of the surface modifier may be in the range of 0.01 to 5% by weight or 0.05 to 3% by weight based on the total weight of the chemical mechanical polishing slurry. If the content of the surface modifier is less than 0.01% by weight, there may be a problem that the surface of the fumed silica is not sufficiently modified, the physical properties of the polishing particles may be uneven, and the polishing efficiency is deteriorated. If the content is 5% by weight or more, there is no increase in the modification effect due to an increase in the content of the modifier, which may cause a problem of inefficiency.

In addition, the chemical mechanical polishing slurry composition may include a pH adjusting agent and a solvent.

The pH adjusting agent has a pH range of 3~7, specifically a pH range of 3~5.5, more specifically 3.5~4.5, of the chemical mechanical polishing slurry in terms of securing the dispersion stability of the slurry composition and forming a zeta potential with excellent polishing efficiency. However, the content of the pH adjusting agent is not particularly limited as long as it satisfies the above pH range.

The pH adjusting agent may be at least one of an acidic or basic pH adjusting agents.

The acidic pH adjusting agents include nitric acid, hydrochloric acid, sulfuric acid, acetic acid, phosphoric acid, formic acid, citric acid, and the like. The basic pH adjusting agent includes potassium hydroxide, sodium hydroxide, tetramethylammonium hydroxide, tetrabutylammonium hydroxide, and the like.

The solvent may be water such as distilled water or deionized water, and may be included in the remaining content excluding the components constituting the polishing slurry.

Additionally, the polishing slurry composition may further include a surfactant.

The surfactant may impart an effect of improving the polishing speed of the carbon layer and discharging CMP by-products. Further, the surfactant forms a physical layer on the ACL layer surface and helps prevent defects and scratches in the periphery as well as carbon protrusions.

The surfactant is an oligomer type amphiphilic surfactant, and an anionic surfactant may be used.

The content of the surfactant may include 0.001 to 0.02% by weight based on the total weight of the chemical mechanical polishing slurry composition.

The polishing slurry composition may further include at least one selected from the group consisting of a biocide, a dispersion stabilizer, and a polishing profile improver.

The biocide may be used to prevent microbial contamination.

The biocide may include isothiazolinone or its derivatives, mMethyl isothiazolinone(MIT, MI), chloromethyl isothiazolinone(CMIT, CMI, MCI), benzisothiazolinone(BIT), octylisothiazolinone(OIT, OI), dichlorooctylisothiazolinone(DCOIT, DCOI), butylbenzisothiazolinone (BBIT), polyhexamethylene guanidine(PHMG) and the like, and one or more selected from these can be used.

The content of the biocide is not particularly limited, but as an example, it may be added in an amount of 0.0001 to 0.05% by weight, specifically 0.005 to 0.03% by weight, based on the total weight of the chemical mechanical polishing slurry composition.

Further, the types and contents of the dispersion stabilizer and the polishing profile improver are not particularly limited, and can be used according to methods well known in this field.

Meanwhile, according to another embodiment of the invention, a method for polishing a semiconductor substrate may include the steps of: preparing a polishing apparatus including a platen to which a soft polishing pad is attached, a head, and a polishing slurry supply unit; arranging the soft polishing pad and a semiconductor substrate including an amorphous carbon layer having surface protrusions formed by a CVD system so as to face each other; supplying a polishing slurry between the soft polishing pad and the semiconductor substrate; and brining the surface of the semiconductor substrate into contact with the surface of the soft polishing pad and then performing polishing to remove surface protrusions of the amorphous carbon layer of the semiconductor substrate. In particular, the polishing slurry comprises a chemical mechanical polishing slurry composition containing modified fumed silica.

The surface protrusion size of the amorphous carbon layer (ACL) may be 3 µm or less or may be 3 µm or more. Specifically, when the surface protrusion size of the amorphous carbon layer (ACL) is 3 µm or less, the range may be 1 to 3 µm or may be 1 µm or less.

The polishing apparatus includes a platen to which a soft polishing pad is attached, a polishing head, and a chemical mechanical polishing slurry composition supply port (not shown). That is, the polishing apparatus may be provided by a method well known in the art except that a soft polishing pad is attached onto the platen, and illustration of the specific structure is omitted.

The platen may be provided with a rotatable means at a lower part thereof. For example, the surface of the platen can be rotated in a constant clockwise or counterclockwise direction by a rotation shaft provided vertically below the surface of the platen.

Moreover, the soft polishing pad may be located on the platen so as to be supported by the platen, and can rotate together with the platen.

The soft polishing pad may have a Shore A hardness of less than 80 or 10 to 80, specifically 20 to 70, more specifically 40 to 60.

The Shore A hardness indicates the hardness of the polishing surface of the soft polishing pad, and is generally measured according to a well-known method, and then, a case where the shore hardness A is 80 or more may be referred to as a hard polishing pad, and a case where the shore hardness A is less than 80 may be referred to as a soft polishing pad.

Thus, according to one embodiment of the invention, by applying the soft polishing pad together with the chemical mechanical polishing slurry composition containing the modified fumed silica described above, it can prevent problems such as breakage of ACL surface protrusions, thereby realizing excellent polishing performance without damage to the hard carbon-based layer of ACL.

The material of such a soft polishing pad is not particularly limited, and any material can be used as long as it has a Shore A hardness within the above range. For example, the soft polishing pad may be a polyurethane material.

The polishing head may be located on the platen to which the soft polishing pad is attached, and may hold an object to be polished. The object to be polished may be a semiconductor substrate such as a wafer. The polishing head may include a rotating shaft that can rotate the object to be polished. In the polishing process, the rotational direction of the polishing head may be opposite to the rotational direction of the platen.

The polishing slurry supply unit can be installed to be connected to a polishing slurry storage tank so as to continuously supply the chemical mechanical polishing slurry having the characteristics described above. The polishing slurry supply unit may be in the form of a nozzle so that a certain amount of polishing slurry can be supplied to the soft polishing pad during the polishing process. However, the present disclosure is not limited thereto and may include an apparatus according to known methods.

The semiconductor substrate includes an ACL having a surface protrusion formed by a CVD system.

Additionally, the polishing apparatus may further include a device well known in the art, in addition to the platen including the soft pad.

When the polishing apparatus including the above configuration is prepared, the soft polishing pad and the semiconductor substrate to be polished are arranged so as to face each other, and a polishing slurry containing the modified fumed silica is supplied through the polishing slurry supply unit between them.

After the polishing slurry is supplied, the surface of the semiconductor substrate and the polishing surface of the soft polishing pad are brought into contact with each other and rotated to polish the surface of the semiconductor substrate, thereby providing a semiconductor substrate having an excellent flatness.

That is, as a polishing slurry containing modified fumed silica as abrasive particles is applied together with a soft pad, only the ACL surface protrusions can be mostly removed in semiconductor substrates including ACL with surface protrusions formed by a CVD system, so that the surface flatness of the semiconductor substrate can be improved more effectively.

At this time, the supply speed of the polishing slurry can be appropriately adjusted based on the size of the object to be polished, and as an example, it can be supplied at a speed of 50 to 400 ml/min or 100 to 300 ml/min from the polishing slurry supply unit.

In addition, in the polishing process, the rotation directions of the platen and the semiconductor substrate to which the soft polishing pad is attached may be opposite to each other, but the present disclosure is not limited thereto.

The rotation speed (rpm) of the platen and the head may affect the CMP polishing speed. Also, if the rotation speed is too high, a phenomenon that scratches or protrusions break on the surface may occur. Therefore, for efficient polishing, the platen can be rotated at a speed of 90 to 100 rpm. The polishing head can be rotated at a speed of 85 to 100 rpm.

The rotation directions of the platen and the polishing head may be opposite to each other.

In the polishing process, a predetermined pressure may be applied, and as an example, a pressure of 0.5 to 5 psi or 0.5 to 3 psi or 1 to 2 psi can be applied. At this time, as the pressure of the polishing process increases, the polishing speed increases, but if the pressure is too high, surface defects may occur due to the phenomenon of splitting (e.g., chipping) or breaking of the protrusions, and if the pressure is too low, the polishing rate may become slow. Therefore, adjusting the pressure within the above range allows efficient progress of polishing.

The polishing process can performed at room temperature.

Hereinafter, Examples of the present disclosure will be described for better understanding. However, the following Examples are given for illustrative purposes only, and are not intended to limit the present disclosure.

### Comparative Examples 1 to 3 and Example 1

### Polishing Method of Semiconductor Substrate Having ACL Deposited Thereon

The semiconductor substrate was polished by using the polishing slurry composition prepared under the following conditions, and using a polishing apparatus having a platen with different types of polishing pads, a header, and a polishing slurry supply unit according to the conditions of Table 1.

In other words, the polishing apparatus used a platen to which a hard pad or a soft pad was attached, respectively. In addition, the polishing slurry composition containing the abrasive in Table 1 was supplied to devices with different types of polishing pads. Through polishing, a semiconductor substrate including an amorphous carbon layer (ACL) having surface protrusions formed by a CVD system was polished.

Then, the surface protrusion removal efficiency of the ACL according to the polishing particle type was measured, and the results are shown in Table 1 below.

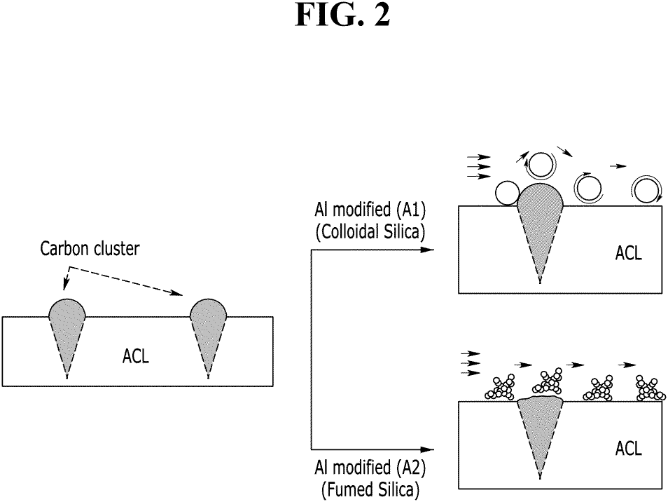

Further, FIG. 2 briefly shows a comparison of methods for removing ACL surface protrusions according to the semiconductor substrate polishing methods of Comparative Example 1 and Example 1.
(1) Polishing object: CVD deposited ACL on semiconductor substrate (removal of surface protrusions)
(2) Polishing slurry composition

### A. Polishing Slurry Composition Containing Modified Colloidal Silica (Al Modified (Al))

Spherical colloidal particles (average particle diameter of 187 nm) and aluminum chloride were added to deionized water, and stirred to initiate the modification reaction. Then, nitric acid and potassium hydroxide, which are pH adjusting agents, were added to adjust the pH to 4, and then an anionic surfactant was added to prepare a polishing slurry composition.

### B. Polishing Slurry Composition With Modified Fumed Silica (A1 Modified (A2))

Amorphous fumed silica particles (average particle diameter of 189 nm) and aluminum nitrate were added to deionized water, and stirred to initiate the modification reaction. Then, nitric acid and potassium hydroxide, which are pH adjusting agents, were added to adjust the pH to 4, and then an anionic surfactant was added to prepare a polishing slurry composition.
(3) CMP conditions
   CMP equipment: CTS^{ⓡ} AP-300
   CMP pressure: 1 psi
   CMP RPM: Platen 93 RPM, Head 87 RPM
   Flow rate: 200 ml/min
   Polishing pad 1: hard polishing pad (Shore A hardness of 90 to 100) (DOW^{ⓡ} IC1010)
   Polishing pad 2: soft polishing pad (Shore A hardness of 40 to 60)
(4) ACL surface protrusion removal efficiency

During ACL deposition by a CVD system, carbon projections were formed on the wafter surface as shown in FIG. 1, and SP2 or SP5 inspection equipment (KLA Tenkor Co.) as shown in FIG. 3 was used to confirm the size, position and number of the formed protrusions.

Subsequently, after finding and confirming the position of the protrusions through RV-G7 equipment measurement, the measurement was performed by a method of confirming the polished state of the surface protrusions before and after polishing through the SEM image of the RV equipment.

That is, the number, size, and positional coordinates of the ACL surface protrusions were extracted and confirmed with the SP2 or SP5 inspection equipment, the position of the protrusions was measured with the RV-G7 equipment, and then the actual shape of the protrusions was confirmed through the SEM provided in the equipment.

Then, the ACL surface protrusions were polished with the polishing slurry for ACL, and then the setup was moved to the same coordinate as the corresponding protrusions before polishing through RV-G7 equipment measurement, and then directly observed through SEM whether or not the same protrusions were removed, remained or split. The efficiency was calculated as a quantitative value according to the following Equation 1.

$$\begin{matrix}\text{Protrusion removal efficiency of amorphous carbon layer} \left(\text{\%}\right) = \\ \left\{\left(\text{Total number of surface protrusions before polishing -}\right)\right) \\ \left(\text{Total number of surface protrusions after polishing}\right) / \\ \left(\text{Total number of surface protrusions before polishing}\right\} \times \text{100}\end{matrix}$$

TABLE 1

| | Abrasive | Abrasive weight (%) | Pressure (psi) | Pad type | Shore A hardness | Protrusion removal efficiency (%) |
|---|---|---|---|---|---|---|
| Comparative Example 1 | Al modified colloidal silica (A1) | 5 | 1 | Hard | 90∼100 | 40∼50 |
| Comparative Example 2 | Al modified colloidal silica (A1) | 5 | 1 | Soft | 40∼60 | 45∼55 |
| Comparative Example 3 | Al modified fumed silica (A2) | 5 | 1 | Hard | 90∼100 | 50∼60 |
| Example 1 | Al modified fumed silica (A2) | 5 | 1 | Soft | 40∼60 | 97∼100 |
| Example 2 | Al modified fumed silica (A2) | 5 | 1 | Soft | 10∼30 | 80-90 |
| Example 3 | Al modified fumed silica (A2) | 5 | 1 | Soft | 60∼80 | 70-80 |

As shown in Table 1, in the case of Comparative Example 1 using colloidal silica as abrasive particles, even if the colloidal particles were modified with an aluminum compound, a commonly used hard-type polishing pad was applied and thus, only up to 50% of the ACL surface protrusions on the semiconductor substrate were removed.

In addition, in the case of Comparative Example 3, even through Al-modified fumed silica was included as polishing particles in the polishing slurry composition, the problem of breaking or tearing of ACL surface protrusions occurred due to the use of a hard type polishing pad, so that ACL surface protrusion removal efficiency remained at only 50 to 60%.

On the other hand, in Example 1, a soft pad, which is advantageous for removing ACL surface protrusions, was applied and at the same time, modified fumed silica particles were introduced as polishing particles, which demonstrated that 97-100% of ACL surface protrusions were effectively removed mostly or completely.

In other words, as shown in FIG. 2, in the case of Comparative Example 1, the Al colloidal silica particles exhibit a spherical shape with a slippery surface, and even though the polishing progresses, they still slide on the ACL surface protrusions, and an effective surface protrusion removal effect cannot be obtained.

However, when the Al-modified fumed silica of Example 1 according to one embodiment was used as polishing particles, as the friction force between the amorphous abrasive particles and the ACL surface protrusions is increased, and at the same time, a soft polishing pad with low hardness is applied together, so that the ACL surface protrusions can be effectively removed without breakage.

What is claimed is:

1. A method of polishing a substrate having amorphous carbon layer deposited thereon, the method comprising:
providing a substrate containing an amorphous carbon layer deposited by a CVD system;
providing a soft polishing pad; and
polishing the substrate while supplying a polishing slurry composition containing modified fumed silica between the substrate and the soft polishing pad.

2. The method according to claim 1, wherein the soft polishing pad has a Shore A hardness of less than 80.

3. The method according to claim 1, wherein the amorphous carbon layer comprises surface protrusions.

4. The method according to claim 3, wherein the polishing removes the surface protrusions of the amorphous carbon layer.

5. The method according to claim 3, wherein a protrusion removal efficiency of the surface protrusions of the amorphous carbon layer is about 80% or higher.

6. The method according to claim 1, wherein the modified fumed silica includes non-spherical, amorphous fumed silica with its surface modified with an aluminum compound.

7. The method according to claim 6, wherein an average particle size of the modified fumed silica is greater than about 150 nm and equal to or less than about 250 nm.

8. The method according to claim 1, wherein the modified fumed silica is contained in an amount of about 0.1 to about 20% by weight based on a total weight of the polishing slurry composition.

9. The method according to claim 1, wherein the polishing slurry composition further comprises a surfactant.
